(19) United States
(12) Patent Application Publication
(10) Pub. No.: US 2017/0018564 A1
(43) Pub. Date: Jan. 19, 2017

(54) SEMICONDUCTOR MEMORY DEVICE AND METHOD FOR MANUFACTURING SAME

(71) Applicant: KABUSHIKI KAISHA TOSHIBA, Minato-ku (JP)

(72) Inventor: Ryota NIHEI, Yokkaichi (JP)

(73) Assignee: KABUSHIKI KAISHA TOSHIBA, Minato-ku (JP)

(21) Appl. No.: 14/935,724

(22) Filed: Nov. 9, 2015

Related U.S. Application Data
(60) Provisional application No. 62/192,288, filed on Jul. 14, 2015.

(51) Int. Cl. H01L 27/115; H01L 29/04

(52) U.S. Cl. CPC H01L 27/11582; H01L 27/1157; H01L 29/04

(57) ABSTRACT

According to one embodiment, a semiconductor memory device includes a substrate, a stacked body provided on the substrate and including multiple electrode layers separately stacked with each other, a semiconductor film, a charge storage film provided between the semiconductor film and the multiple electrode layers, and a first insulating film provided between the semiconductor film and the charge storage film, extending in the stacking direction, and having a bottom surface contacting the substrate. The semiconductor film is provided integrally with the substrate in the stacked body, and extends in a stacking direction of the stacked body. An orientation of a crystal structure of the semiconductor film is equal to an orientation of a crystal structure of the substrate.

### CROSS-REFERENCE TO RELATED APPLICATIONS

This application is based upon and claims the benefit of priority from U.S. Provisional Patent Application 62/192,288 field on Jul. 14, 2015; the entire contents of which are incorporated herein by reference.

### FIELD

Embodiments described herein relate generally to a semiconductor memory device and a method for manufacturing same.

### BACKGROUND

A memory device having a three-dimensional structure is proposed, in which memory holes are formed in a stacked body including multiple electrode layers that function as control gates in memory cells and are separately stacked with each other, and a silicon body serving as a channel is provided on a side wall of the memory hole via a charge storage film.

Regarding the three-dimensional device stated above, there is a fear that device characteristics are degraded by miniaturization.

### BRIEF DESCRIPTION OF THE DRAWINGS

FIG. 1 is a schematic perspective view of a memory cell array of an embodiment;

FIGS. 2A and 2B are enlarged schematic cross-sectional views of a part of the columnar portion of the embodiment;

FIG. 3A is a schematic perspective view of the semiconductor device of the embodiment and FIG. 3B is a cross-sectional view of the semiconductor device of the embodiment;

FIGS. 4A and 4B are schematic perspective views of a periphery of interconnects of the embodiment and FIG. 4C is a cross-sectional view of the periphery of the interconnects of the embodiment; and

FIG. 5A to FIG. 24D are schematic cross-sectional views showing a method for manufacturing the semiconductor memory device of the embodiment.

### DETAILED DESCRIPTION

According to one embodiment, a semiconductor memory device includes a substrate, a stacked body provided on the substrate and including multiple electrode layers separately stacked with each other, a semiconductor film, a charge storage film provided between the semiconductor film and the multiple electrode layers, and a first insulating film provided between the semiconductor film and the charge storage film, extending in the stacking direction, and having a bottom surface contacting the substrate. The semiconductor film is provided integrally with the substrate in the stacked body, extends in a stacking direction of the stacked body. An orientation of a crystal structure of the semiconductor film is equal to an orientation of a crystal structure of the substrate.

Hereinafter, embodiments will be described with reference to the drawings. Incidentally, the same components in the respective drawings are denoted by the same reference characters.

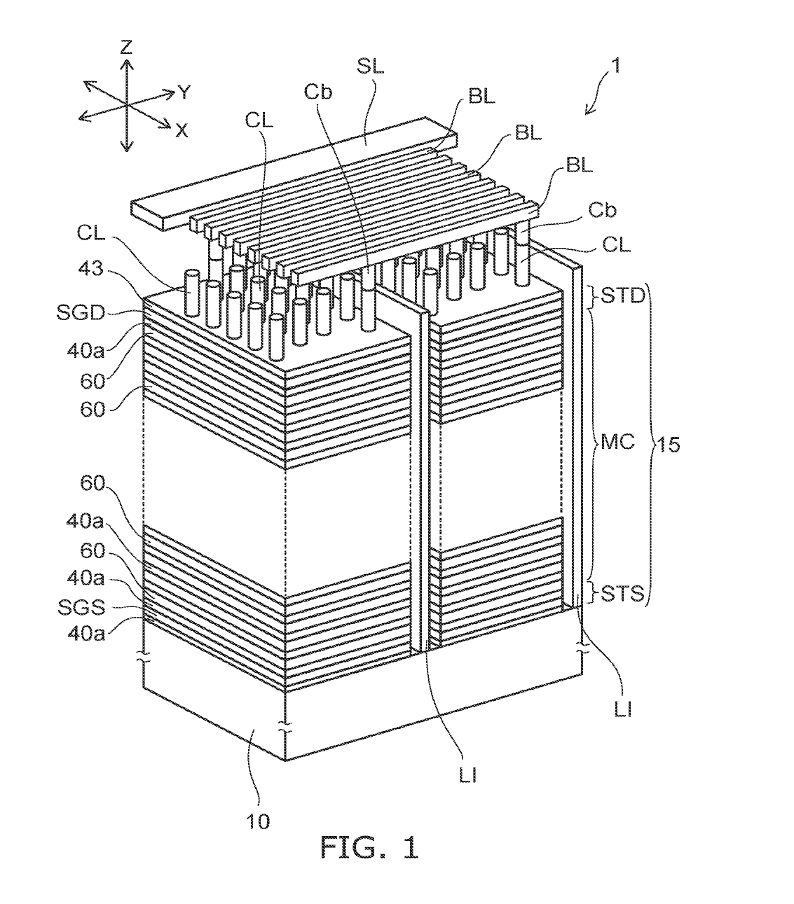

FIG. 1 is a schematic perspective view of a memory cell array 1 of an embodiment. Incidentally, in FIG. 1, illustrations of insulating layers and conducting layers on a stacked body are omitted in order to make the drawings easy to see.

In FIG. 1, two directions orthogonal to each other are an X-direction and a Y-direction, and a direction which is orthogonal to the X-direction and the Y-direction (X-Y plane) and in which electrode layers 60 are stacked is a Z-direction (stacking direction).

As shown in FIG. 1, the memory cell array 1 includes a substrate 10, a stacked body 15, multiple columnar portions CL, an interconnect portion LI, and an upper layer interconnect. FIG. 1 shows bit lines BL and a source layer SL as the upper layer interconnect.

A source-side select gate SGS is provided on the substrate 10 through an insulating portion 40a. The stacked body 15 is provided on the source-side select gate SGS. A drain-side select gate SGD is provided on the stacked body 15.

The stacked body 15 includes the electrode layers 60 and multiple insulating portions 40a. The electrode layers 60 are separately stacked with each other. The insulating portions 40a are provided between the electrode layers 60. The insulating portions 40a are provided in the uppermost layer and the lowermost layer of the stacked body 15. For example, the electrode layers 60 and the insulating portions 40a are alternately stacked layer by layer. Incidentally, the layer number of the electrode layers 60 shown in the drawing is one example, and the layer number of the electrode layers 60 is arbitrary.

The substrate 10 contains, for example, silicon. The electrode layer 60 is a layer mainly containing silicon, and is, for example, a single crystal silicon layer. The electrode layer 60 contains, for example, boron as an impurity for giving conductivity to, for example, the silicon layer. Besides, the electrode layer 60 contains, for example, metal such as tungsten or molybdenum and may include metal silicide.

The drain-side select gate SGD and the source-side select gate SGS contain, for example, the same material as that of the electrode layer 60. The insulating portion 40a includes, for example, a gap. The insulating portion may include, for example, an insulating film mainly containing silicon.

The thickness of the drain-side select gate SGS and the thickness of the source-side select gate SGS are thicker than, for example, the thickness of one layer of the electrode layers 60, and multiple layers may be provided. Incidentally, the thickness of the drain-side select gate SGD and the thickness of the source-side select gate SGS may be equal to or thinner than the thickness of one layer of the electrode layers 60. In that case, multiple layers may be provided similarly to the foregoing. Incidentally, the “thickness” here indicates the thickness in the stacking direction (Z-direction) of the stacked body 15.

The columnar portions CL extending in the Z-direction are provided in the stacked body 15. The columnar portion CL is formed into, for example, a cylindrical or elliptic cylindrical shape. The columnar portions CL are positioned in, for example, a staggered arrangement. Alternatively, the columnar portions CL may be arranged in a square grid pattern along the X-direction and the Y-direction. The columnar portions CL are electrically connected to the substrate 10.

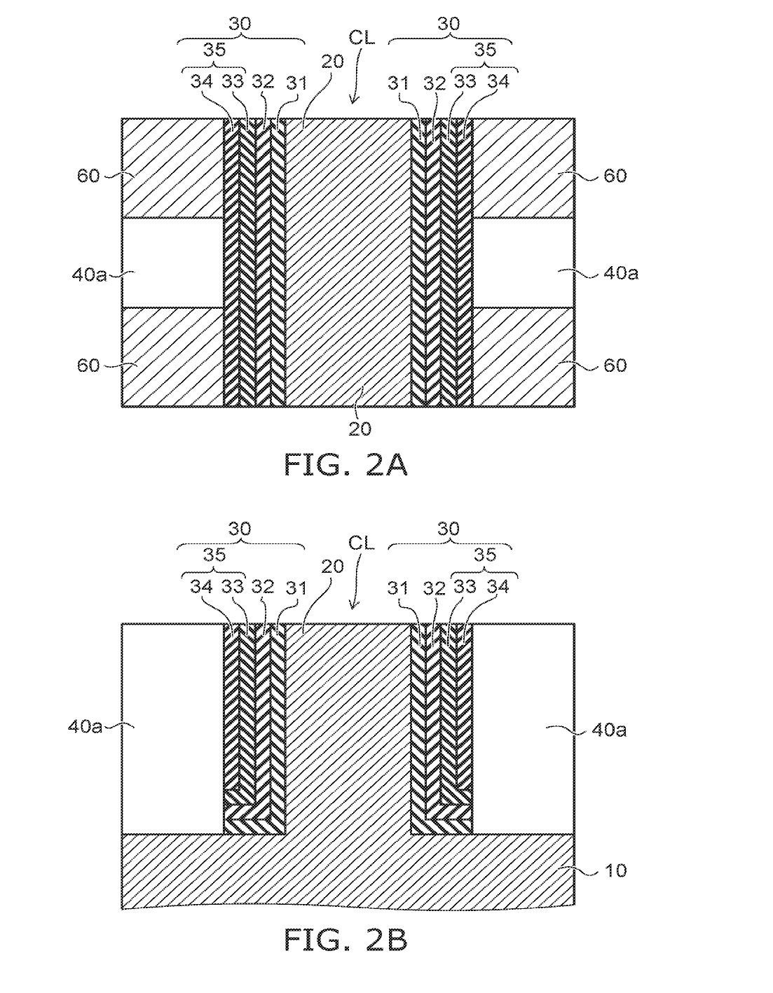

The columnar portion CL includes a channel body 20 and a memory film 30 shown in FIG. 2A. The memory film 30 is provided between the stacked body 15 and the channel body 20. The memory film 30 and the channel body 20 extend along the Z-direction.

The channel body 20 is, for example, columnar. The channel body 20 contains, for example, silicon. For example, the crystal structure orientation of the channel body 20 is equal to the crystal structure orientation of the substrate 10. Incidentally, the crystal structure orientation of the substrate 10 is the orientation at an interface (upper surface) between the substrate 10 and the stacked body 15. The crystal structure orientation of the channel body 20 is the orientation at a bottom surface of the channel body 20 covered with the memory film 30. Besides, the expression “equal to the crystal structure orientation” includes that the orientations of the substrate 10 and the channel body 20 are parallel to each other, and includes that the atomic arrangements of the substrate 10 and the channel body 20 are equal to each other.

The interconnect portion LI spreading in the X-direction and the Z-direction in the stacked body 15 is provided in the stacked body 15. The interconnect portion LI is sandwiched between the stacked bodies 15. An insulating film is provided on a side wall of the interconnect portion LI. A conductive film is provided on an inner side of the insulating film. The insulating film and the conductive film spread in the X-direction and the Z-direction similarly to the interconnect portion LI.

A lower end of the interconnect portion LI is electrically connected to the channel body 20 (semiconductor film) in the columnar portion CL through the substrate 10. An upper part of the interconnect portion LI is electrically connected to a not-shown control circuit through a contact layer, the source layer SL and the interconnect.

The bit lines BL (for example, metal films) are provided on the stacked body 15. The bit lines BL are separated from each other in the X-direction, and extend in the Y-direction.

An upper end of the channel body 20 is connected to the bit line BL (interconnect) shown in FIG. 1, and a lower end side of the channel body 20 is provided integrally with the substrate 10 as shown in FIG. 2B. Each of the bit lines BL extends in the Y-direction.

Multiple channel bodies 20 are connected to one common bit line BL, and the channel bodies 20 are selected one by one from the respective areas of the columnar portions CL separated in the Y-direction.

A drain-side select transistor STD is provided at an upper end portion of the columnar portion CL, and a source-side select transistor STS is provided at a lower end portion thereof.

A memory cell MC, the drain-side select transistor STD and the source-side select transistor STS are vertical transistors in which current flows in the stacking direction (Z-direction) of the stacked body 15.

The respective select gates SGD and SGS function as gate electrodes (control gates) of the respective select transistors STD and STS. The insulating film (memory film 30) functioning as the gate insulating film of each of the select transistors STD and STS is provided between each of the select gates SGD and SGS and the channel body 20.

Multiple memory cells MC, in which electrode layers 60 are provided as control gates, are positioned between the drain-side transistor STD and the source-side select transistor STS.

The memory cells MC, the drain-side select transistor STD and the source-side select transistor STS are connected in series through the channel body 20, and constitute one memory string. The memory strings are arranged in, for example, a staggered arrangement in a plane direction parallel to the X-Y plane, so that the memory cells MC are three-dimensionally provided in the X-direction, the Y-direction and the Z-direction.

The semiconductor memory device of the embodiment can electrically freely perform erasing and writing of data, and even if power is turned off, memory contents can be held.

An example of the memory cell MC of the embodiment will be described with reference to FIG. 2A and FIG. 2B.

FIG. 2A is an enlarged schematic sectional view of a part of the columnar portion CL of the embodiment, and FIG. 2B is an enlarged schematic sectional view of a lower end portion of the columnar portion CL.

The memory cell MC is, for example, of a charge-trap type, and includes the electrode layer 60, the memory film 30 and the channel body 20. The channel body 20 functions as a channel in the memory cell MC, and the electrode layer 60 functions as a control gate of the memory cell MC. The memory film 30 functions as a data storage layer which stores electrical charges injected from the channel body 20. That is, the memory cell MC including a structure in which the control gate surrounds the channel is formed at each of crossing portions between the channel body 20 and the electrode layers 60.

As shown in FIG. 2A, the memory film 30 includes, for example, a block insulating film 35 (second insulating film), a charge storage film 32 and a tunnel insulating film 31 (first insulating film). The block insulating film 35 contacts the electrode layer 60, and the tunnel insulating film 31 contacts the channel body 20. The charge storage film 32 is provided between the block insulating film 35 and the tunnel insulating film 31.

As shown in FIG. 2B, a bottom surface of the block insulating film 35 contacts the charge storage film 32. The bottom surface of the block insulating film 35 is more separated from the upper surface of the substrate 10 than a bottom surface of the charge storage film 32. The area of the bottom surface of the block insulating film 35 is smaller than the area of the bottom surface of the charge storage film 32.

The bottom surface of the charge storage film 32 contacts the tunnel insulating film 31. The bottom surface of the charge storage film 32 is more separated from the upper surface of the substrate 10 than a bottom surface of the tunnel insulating film 31. The area of the bottom surface of the charge storage film 32 is smaller than the area of the bottom surface of the tunnel insulating film 31. The bottom surface of the tunnel insulating film 31 contacts the substrate 10. The charge storage film 32 is separated from the channel body 20.

The block insulating film 35 prevents electrical charges stored in the charge storage film 32 from diffusing to the electrode layer 60. The block insulating film 35 includes, for example, a cap film 34 and a block film 33. The block film 33 is provided between the cap film 34 and the charge storage film 32. The block film 33 is, for example, a silicon oxide film.

The cap film 34 is provided to contact the electrode layer 60. The cap film 34 is a film having a higher dielectric constant than the block film 33, and includes, for example, a silicon nitride film. For example, either a silicon nitride film or an aluminum oxide is used as the cap film 34. The cap film 34 is provided to contact the electrode layer 60, so that back-tunneling electrons injected from the electrode layer 60 in erasing can be suppressed. That is, when the stacked film including the silicon oxide film and either the silicon nitride film or the high dielectric constant oxide film is used as the block insulating film 35, a charge blocking property can be enhanced.

The charge storage film 32 includes many trap sites to capture charges, and is, for example, a silicon nitride film.

The tunnel insulating film 31 becomes a potential barrier when charges are injected from the channel body 20 into the charge storage film 32, or when charges stored in the charge storage film 32 diffuse into the channel body 20. The tunnel insulating film 31 is, for example, a silicon oxide film.

Alternately, a stacked film (ONO film) having a structure in which a silicon nitride film is sandwiched between a pair of silicon oxide films may be used as the tunnel insulating film 31. When the ONO film is used as the tunnel insulating film 31, an erasing operation can be performed at a low electric field as compared with the single layer of the silicon oxide film.

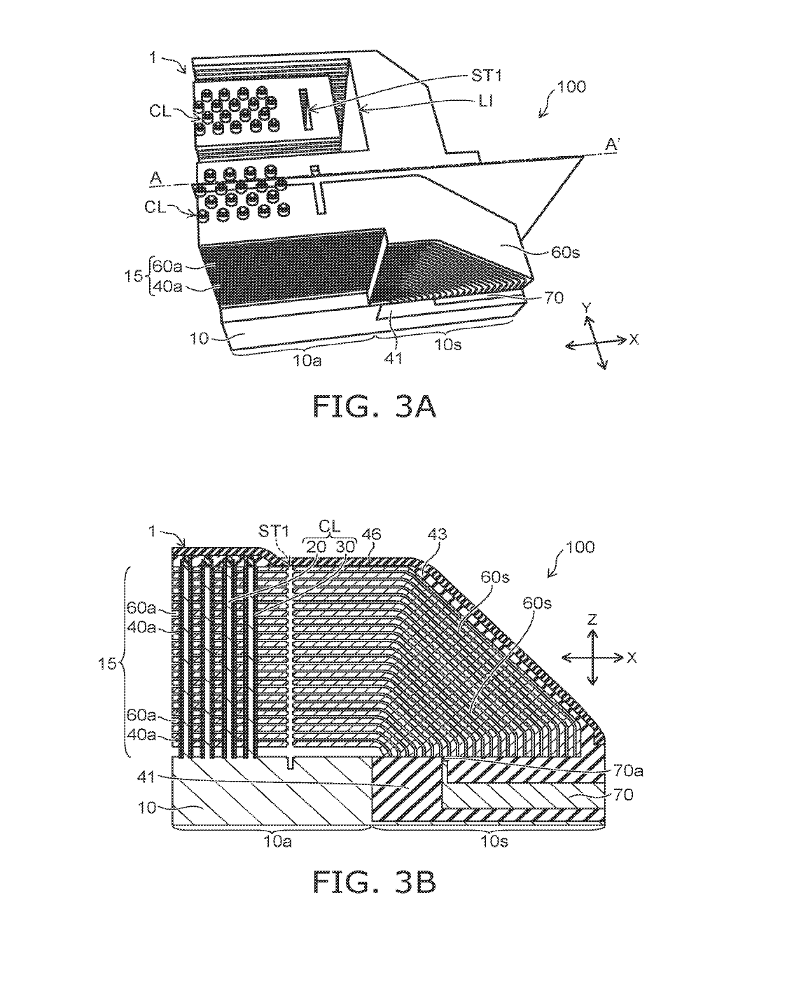

The configuration of a semiconductor memory device 100 of the embodiment will be described with reference to FIG. 3A and FIG. 3B.

FIG. 3A is a schematic perspective view of the semiconductor memory device 100 of the embodiment, and FIG. 3B is a schematic sectional view corresponding to A-A′ of FIG. 3A. Incidentally, in FIG. 3A, illustration of a structure above the stacked body 15 is omitted in order to make the drawing easy to see.

As shown in FIG. 3A and FIG. 3B, the substrate 10 includes a memory area 10a and a connection area 10s. The upper surface height of the memory area 10a is higher than the height of the connection area 10s. Incidentally, the “height” here is the height in the Z-direction (stacking direction). The memory cell array 1 and a slit ST1 are provided on the memory area 10a.

The slit ST1 extends in the Z-direction and is provided integrally with the insulating portions 40a. An upper surface of the slit ST1 is covered with an insulating film 46.

The interconnect portion LI spreading in the X-Z plane and the Y-Z plane is integrally provided in the periphery of the memory cell array 1 and the slit ST1.

Multiple electrode layers 60 (connection portions) extending from the memory area 10a are provided on the connection area 10s. That is, the multiple electrode layers 60 are integrally provided from the memory area 10a to the connection area 10s, and are separately stacked with each other. Incidentally, in the following, there is a case where a description is made while multiple electrode layers 60 are called multiple electrode layers 60a provided on the memory area 10a and multiple electrode layers 60s provided on the connection area 10s.

The electrode layer 60a spreads in the X-Y plane. On the other hand, the electrode layer 60s spreads in a direction inclined to the X-Y plane.

An insulating layer 41 is provided between the substrate 10 and the multiple electrode layers 60s. The insulating layer 41 contacts a side surface of the memory area 10a of the substrate 10. An upper surface of the insulating layer 41 is provided on the X-Y plane where an upper surface of the memory area 10a of the substrate 10 is provided. That is, the upper surface of the insulating layer 41 is coplanar with the upper surface of the memory area 10a of the substrate 10. Multiple interconnects 70 are provided in the insulating layer 41.

Each of the interconnects 70 includes an end 70a. The end 70a is provided on an upper surface of the interconnect 70 extending in the Z-direction.

The end 70a contacts the electrode layer 60s. Hereby, the electrode layer 60 is electrically connected to the interconnect 70. The end 70a contains, for example, the same material as the electrode layer 60, and contains, for example, silicon.

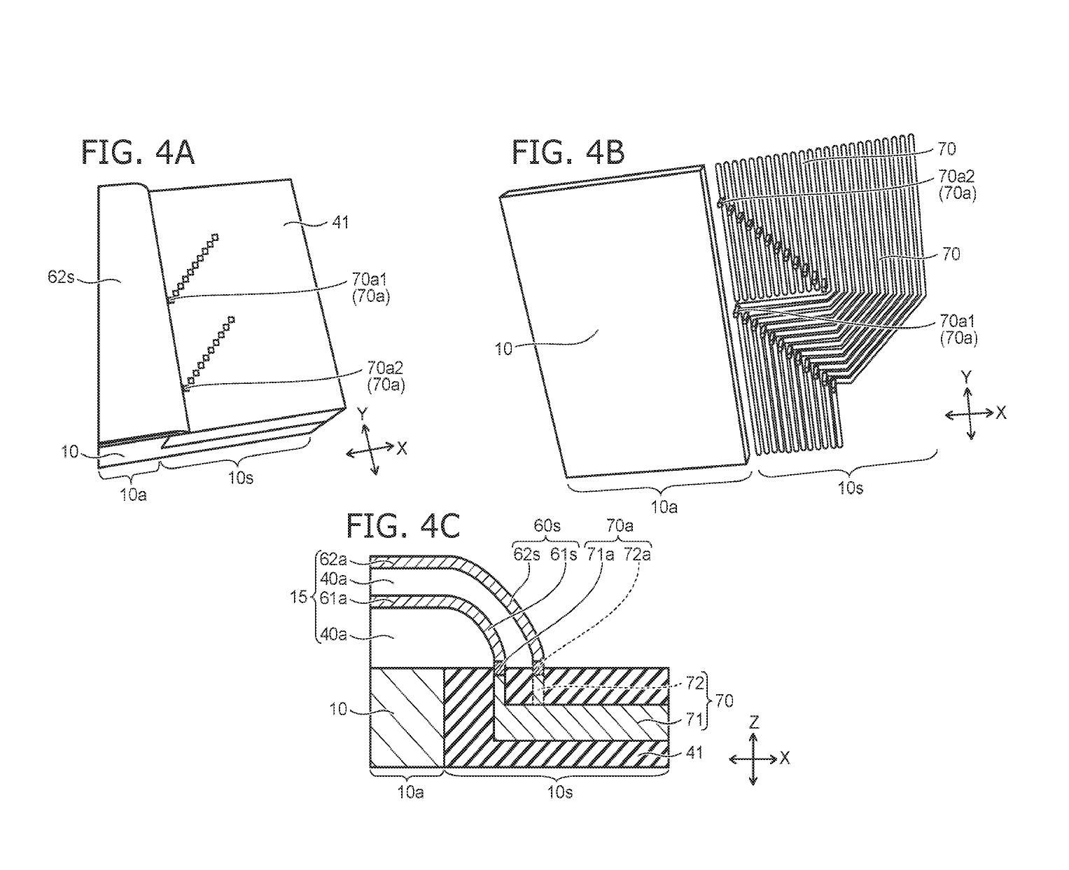

The configuration of the periphery of the interconnects 70 will be described with reference to FIG. 4A to FIG. 4C. FIG. 4A is a schematic perspective view of the periphery of the interconnects 70, FIG. 4B is a schematic perspective view of the interconnects 70 as viewed from the lower side of FIG. 4A, and FIG. 4C is a schematic sectional view of the periphery of the interconnects 70. Incidentally, in FIG. 4A and FIG. 4C, the illustration above the second layer of the electrode layers 60 is omitted in order to make the drawings easy to see.

As shown in FIG. 4A and FIG. 4B, the multiple interconnects 70 are provided on, for example, the same plane, and are separated from each other. Thus, an upper surface of one of the interconnects 70 is coplanar with upper surface of another one of the interconnects 70. Each of the interconnects 70 is electrically connected to a not-shown peripheral circuit. Multiple interconnects 70 extend in, for example, the X-direction.

Multiple ends 70a are coplanar with and are separated from each other. The multiple ends 70a respectively contacts, for example, the electrode layers 60s of different layers.

The multiple ends 70a are provided at an arbitrary interval in the X-direction and the Y-direction. The multiple ends 70a are provided along, for example, the Y-direction. The interval at which the multiple ends 70a are provided may be the interval at which the multiple interconnects 70 are separately provided from each other.

For example, an end 70a2 is provided side by side from an end 70a1 in the Y-direction. The interconnect 70 including the end 70a2 is separated from another interconnect 70.

At this time, the electrode layer 60s in contact with the end 70a2 contacts the electrode layer 60s different from the end 70a1. In this case, for example, the electrode layer 60s in contact with the end 70a2 covers the electrode layer 60s in contact with the end 70a1.

As shown in FIG. 4C, an electrode layer 61s contacts an end 71a. An electrode layer 62s is separated from and covers an upper surface of the electrode layer 61s, and contacts an end 72a. A surface of the electrode layer 62s in contact with the end 72a is coplanar with a surface of the electrode layer 61s in contact with the end 71a.

The height at which the interconnect 70 is provided is lower than the height of the upper surface of the memory area 10a of the substrate 10. For example, a surface of the electrode layer 62s in contact with the end 72a is coplanar with the upper surface of the substrate 10 in the memory area 10a.

The height of the surface of the electrode layer 61s in contact with the end 71a is lower than the height at which an electrode layer 61a is provided. The distance between the end 71a and the channel body 20 is shorter than the distance between the end 72a and the channel body 20.

The height of the surface of the electrode layer 62s in contact with an electrode layer 62a is higher than the height at which the electrode layer 61a is provided. The height of the surface of the electrode layer 62s in contact with the end 72a is lower than the height at which the electrode layer 61a is provided.

According to the embodiment, the channel body 20 is provided integrally with the substrate 10. The crystal structure orientation of the channel body 20 is equal to the crystal structure orientation of the substrate 10. Hereby, electric resistance between the channel body 20 and the substrate 10 can be reduced, and degradation of characteristics due to miniaturization can be suppressed.

Further, the lower end of the charge storage film 32 is separated from the channel body 20. For example, when the columnar portion CL is formed, there is a case where a hole is formed, and the memory film 30 is formed from a side wall of the hole. At that time, the lower end of the charge storage film 32 may contact the channel body 20. Hereby, there is a possibility that the characteristics of the memory cell MC are degraded.

On the other hand, according to the embodiment, the tunnel insulating film 31 contacts the channel body 20, extends in the Z-direction, and contacts the substrate 10. Thus, the lower end of the charge storage film 32 is separated from the channel body 20. Hereby, an electric field is not concentrated to the memory cell MC provided in the lowermost layer of the stacked body 15. Thus, degradation of characteristics can be suppressed.

In addition to the above, according to the embodiment, the multiple electrode layers 60s respectively include the surfaces in contact with the multiple ends 70a being coplanar with each other. Thus, the electrode layers 60a provided on the memory area 10a are electrically connected to the interconnects 70 through the electrode layers 60s and the ends 70a. As described later, a process of connecting the electrode layer 60a and the end 70a uses, for example, an epitaxial growth method. Hereby, high-precision formation of the connection portion is enabled as compared with a process of forming the connection portion by processing the electrode layer 60s. Thus, degradation of characteristics due to miniaturization can be suppressed.

For example, when a method of stepwise process of the electrode layers 60s is used, as the number of layers increases, the number of times of lithography increases, and the cost increases. On the other hand, according to the embodiment, even if the number of layers increases, the layers are not required to be processed stepwise. Thus, the cost increase due to the increase of the number of times of lithography can be suppressed.

Further, according to the embodiment, the electrode layer 60s connected to the end 70a is provided integrally with the electrode layer 60a of the memory cell MC. Hereby, interfaces between members are small between the electrode layer 60a and the interconnect 70 as compared with a case where a connection member such as a contact portion is formed. Thus, electric resistance between the electrode layer 60a and the interconnect 70 can be reduced, and degradation of characteristics due to miniaturization can be suppressed.

According to the embodiment, the multiple ends 70a provided side by side in the Y-direction respectively contact the different electrode layers 60s. Hereby, enlargement of the area in the X-direction due to the increase of the interconnects 70 can be suppressed.

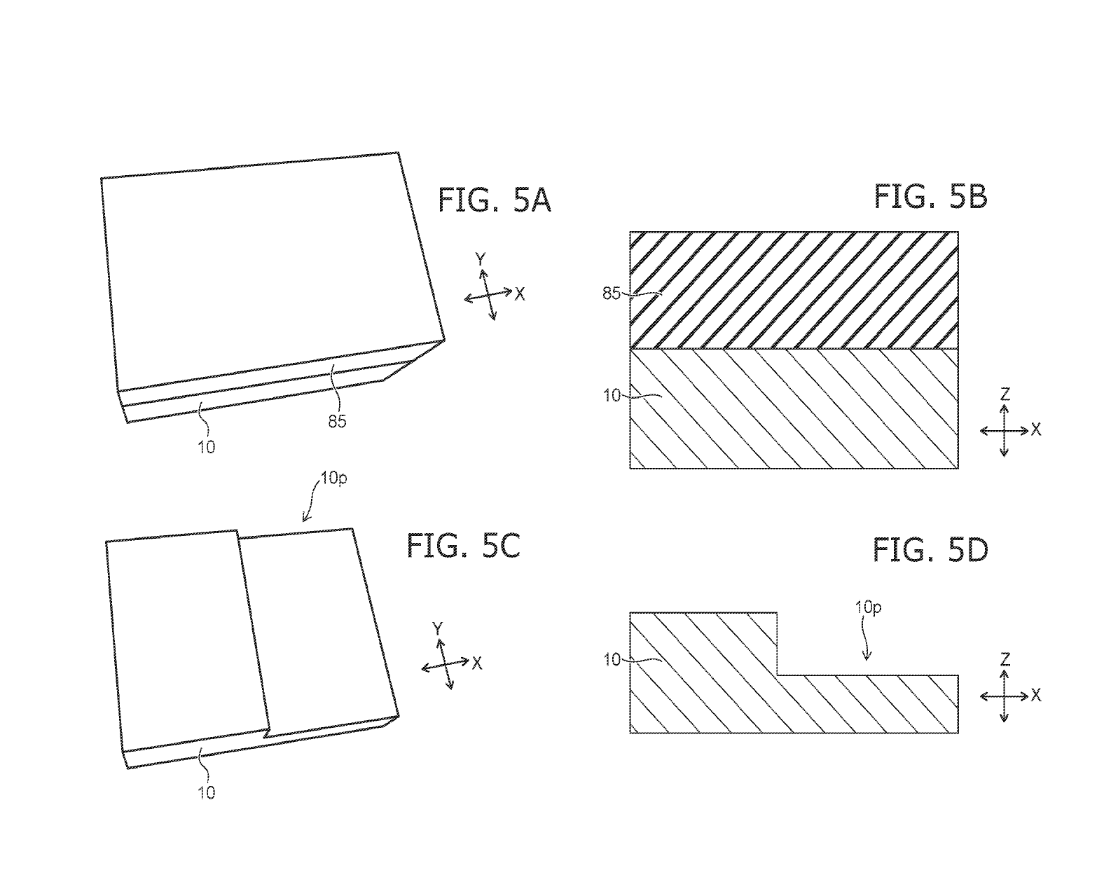

A method for manufacturing the semiconductor memory device of the embodiment will be described with reference to FIG. 5A to FIG. 24D.

As shown in FIG. 5A and FIG. 5B, a resist film 85 is formed on a substrate 10. The substrate 10 contains, for example, silicon.

As shown in FIG. 5C and FIG. 5D, a space 10p is formed on the substrate 10. For example, a PEP method (Photo Engraving Process) is used as a method of forming the space 10p, and a part of the resist film 85 is removed. Then, the substrate 10 exposed in the removed portion is removed. Thereafter, the resist film 85 remaining on the substrate 10 is removed. Hereby, the space 10p is formed.

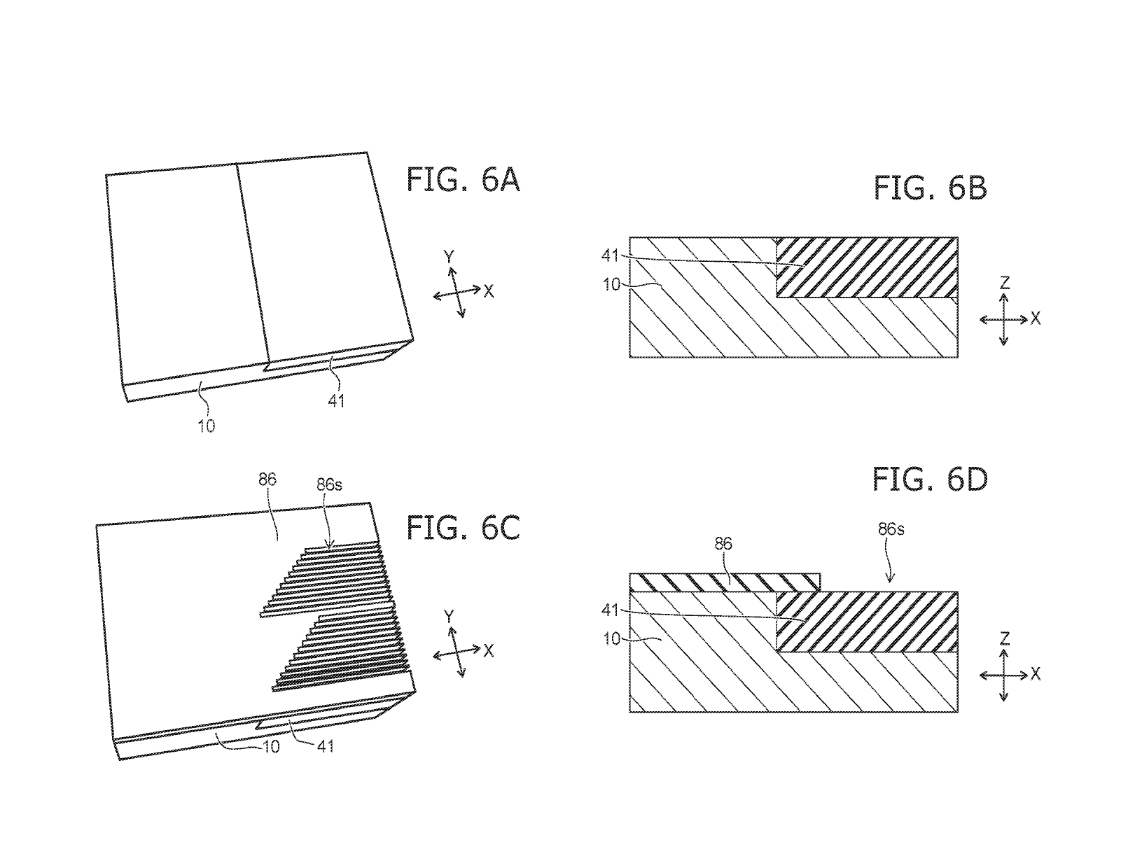

As shown in FIG. 6A and FIG. 6B, an insulating layer 41 is formed in the space 10p. The upper surface of the insulating layer 41 is coplanar with, for example, the upper surface of the substrate 10. For example, a silicon oxide film is used as the insulating layer 41.

As shown in FIG. 6C and FIG. 6D, a resist film 86 is formed on the substrate 10 and the insulating layer 41. A pattern 86s is formed in the resist film 86 on the insulating layer 41 by using, for example, the PEP method.

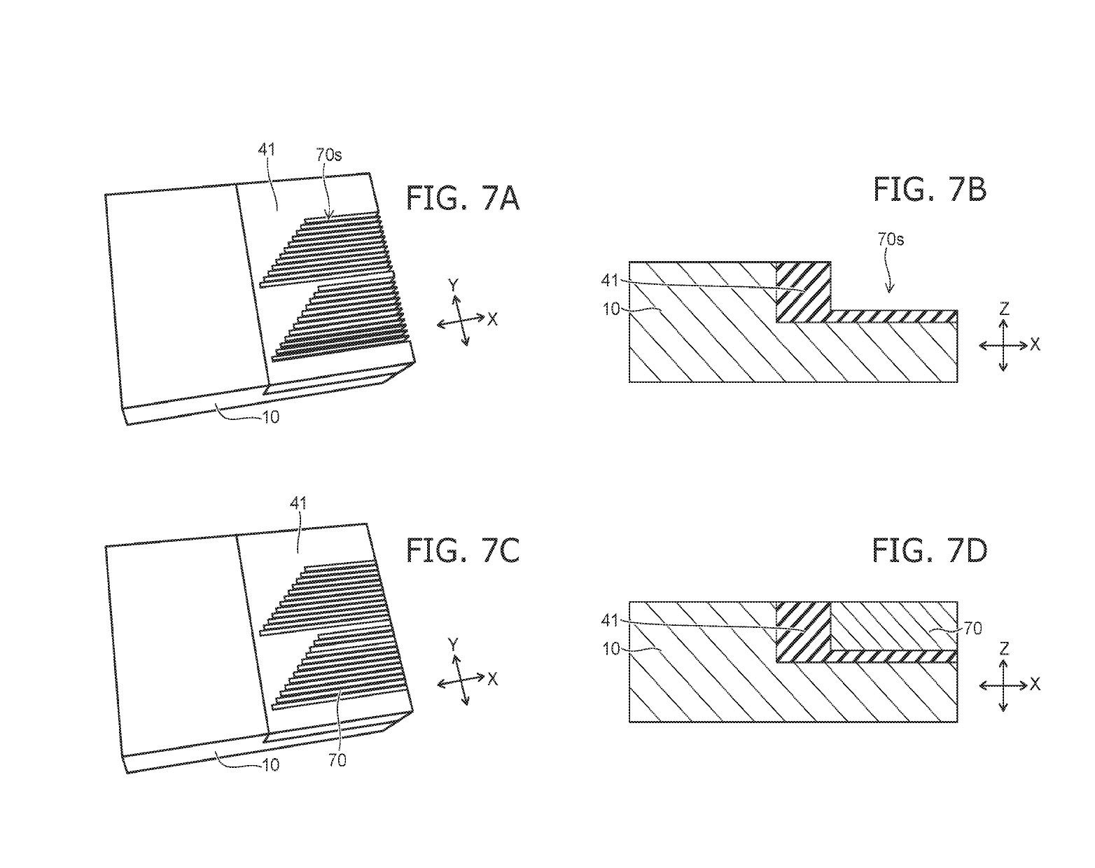

As shown in FIG. 7A and FIG. 7B, a pattern 70s is formed in the insulating layer 41. The pattern 70s is formed by, for example, an RIE method (Reactive Ion Etching) using the resist film 86 as a mask.

As shown in FIG. 7C and FIG. 7D, interconnects 70 are formed in the insulating layer 41. As a method of forming the interconnects 70, for example, a conductive film is formed on the substrate 10, in the pattern 70s and on the insulating layer 41. Thereafter, the conductive film formed on the substrate 10 and on the insulating layer 41 is removed. Hereby, the interconnects 70 are formed. For example, polysilicon is used as the conductive film.

The multiple interconnects 70 are formed and are separated from each other.

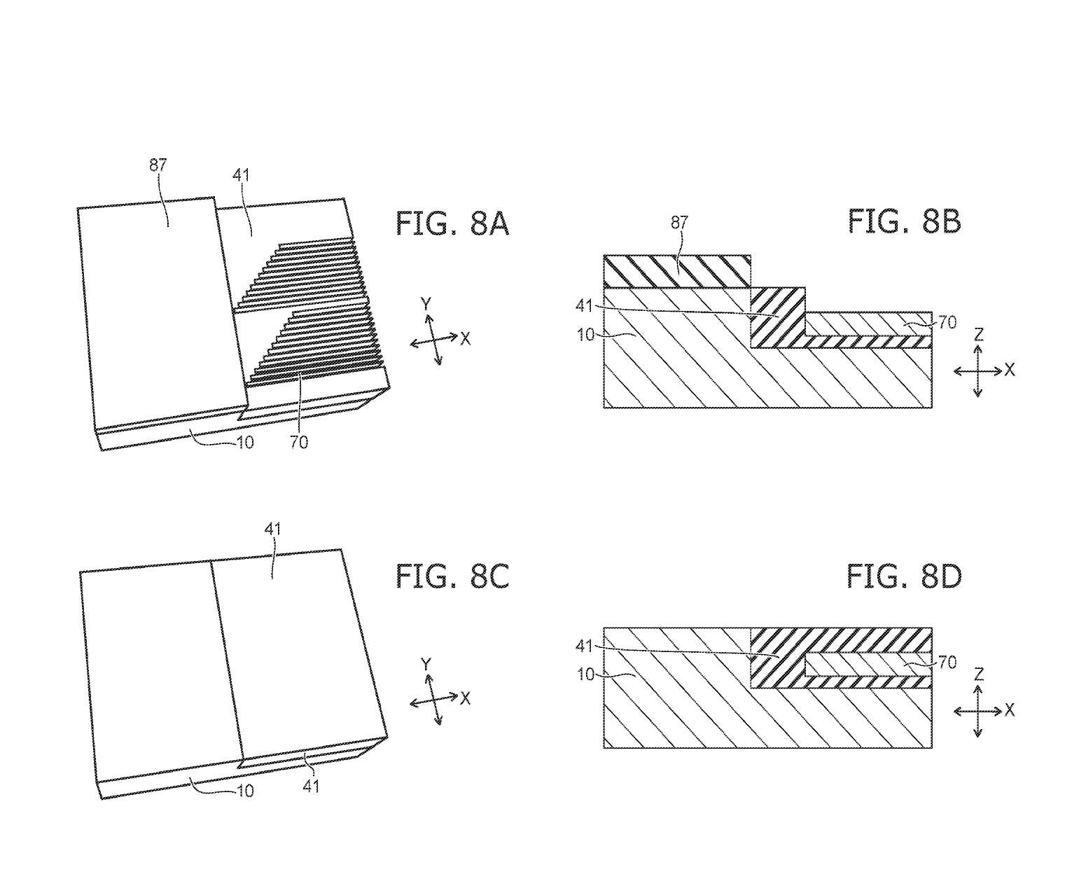

As shown in FIG. 8A and FIG. 8B, a resist film 87 is formed on the substrate 10. Thereafter, upper parts of the interconnects 70 are recessed (etched back). The resist film 87 is formed on the substrate 10, so that only the upper surfaces of the interconnects 70 can be recessed.

As shown in FIG. 8C and FIG. 8D, an insulating layer 41 is formed in portions where the interconnects 70 are recessed. Hereby, the upper surfaces of the interconnects 70 are covered with the insulating layer 41. The upper surface of the insulating layer 41 is coplanar with, for example, the upper surface of the substrate 10.

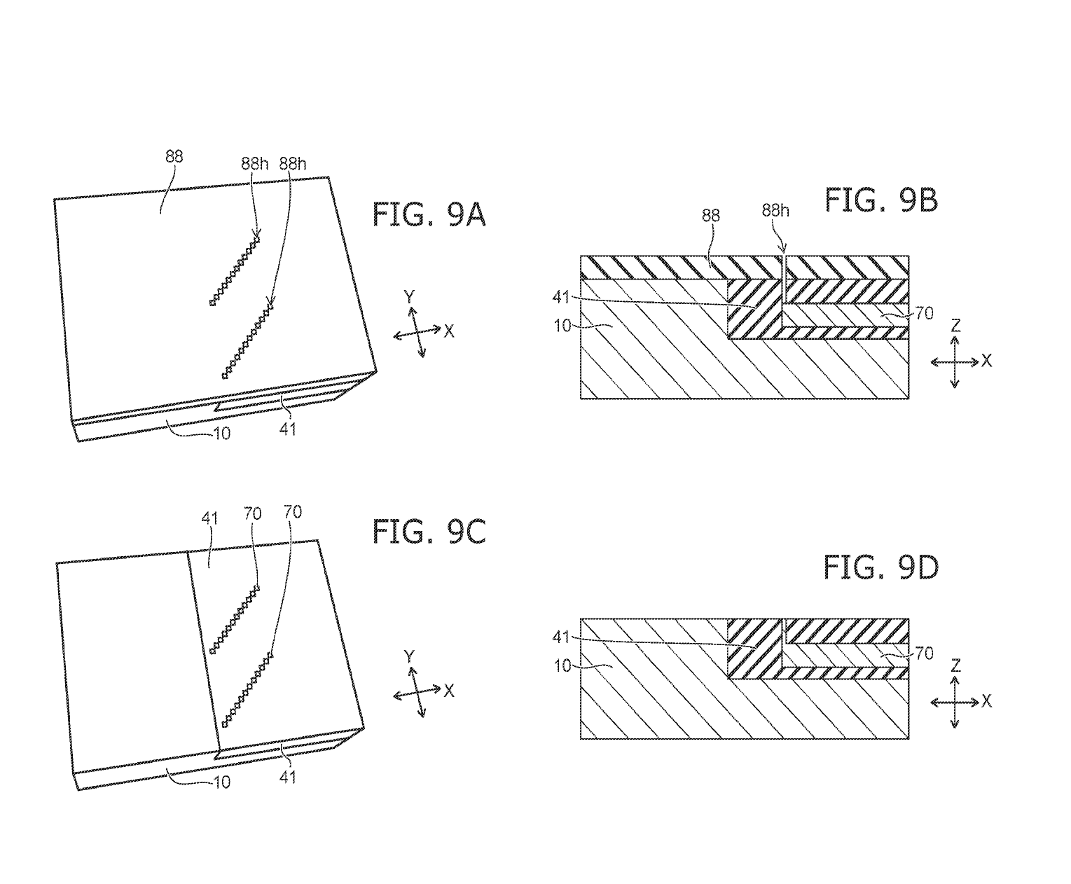

As shown in FIG. 9A and FIG. 9B, a resist film 88 is formed on the substrate 10 and the insulating layer 41. A pattern is formed in the resist film 88 on the insulating layer 41 by using, for example, the PEP method.

Thereafter, holes 88h piercing the insulating layer 41 exposed in the pattern and reaching the interconnects 70 are formed by, for example, the RIE method using the resist film 88 as a mask. The multiple holes 88h are formed on the upper surfaces of the respective interconnects 70.

As shown in FIG. 9C and FIG. 9D, the resist film 88 is removed. Thereafter, conductive films are formed in the holes 88h. Hereby, the interconnects 70 are integrally formed from the inside of the insulating layer 41 to the upper surface.

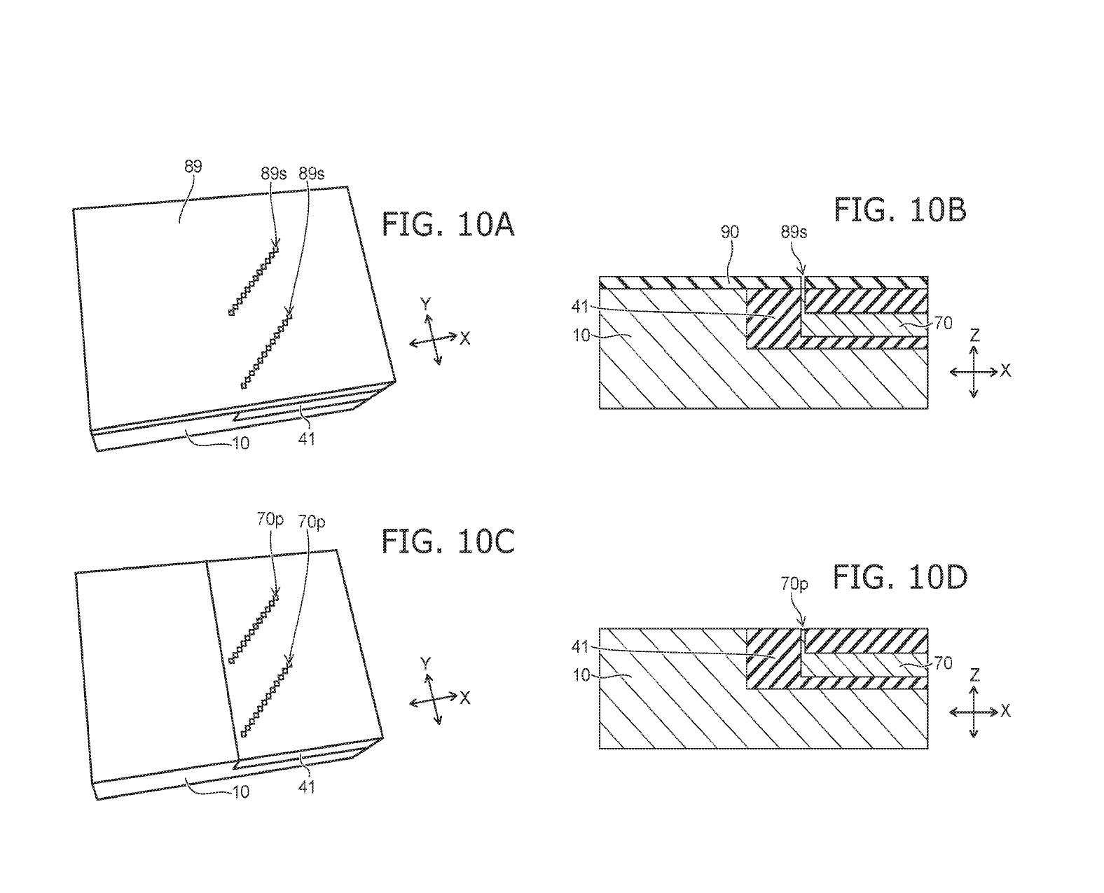

As shown in FIG. 10A and FIG. 10B, a resist film 89 is formed on the upper surface of the substrate 10, the upper surface of the insulating layer 41, and the upper surfaces of the interconnects 70. A pattern 89s is formed in the resist film 89 on the interconnects 70 by using, for example, the PEP method.

As shown in FIG. 10C and FIG. 10D, the upper parts of the interconnects 70 are recessed, and spaces 70p are formed. Thereafter, the resist film 89 is removed.

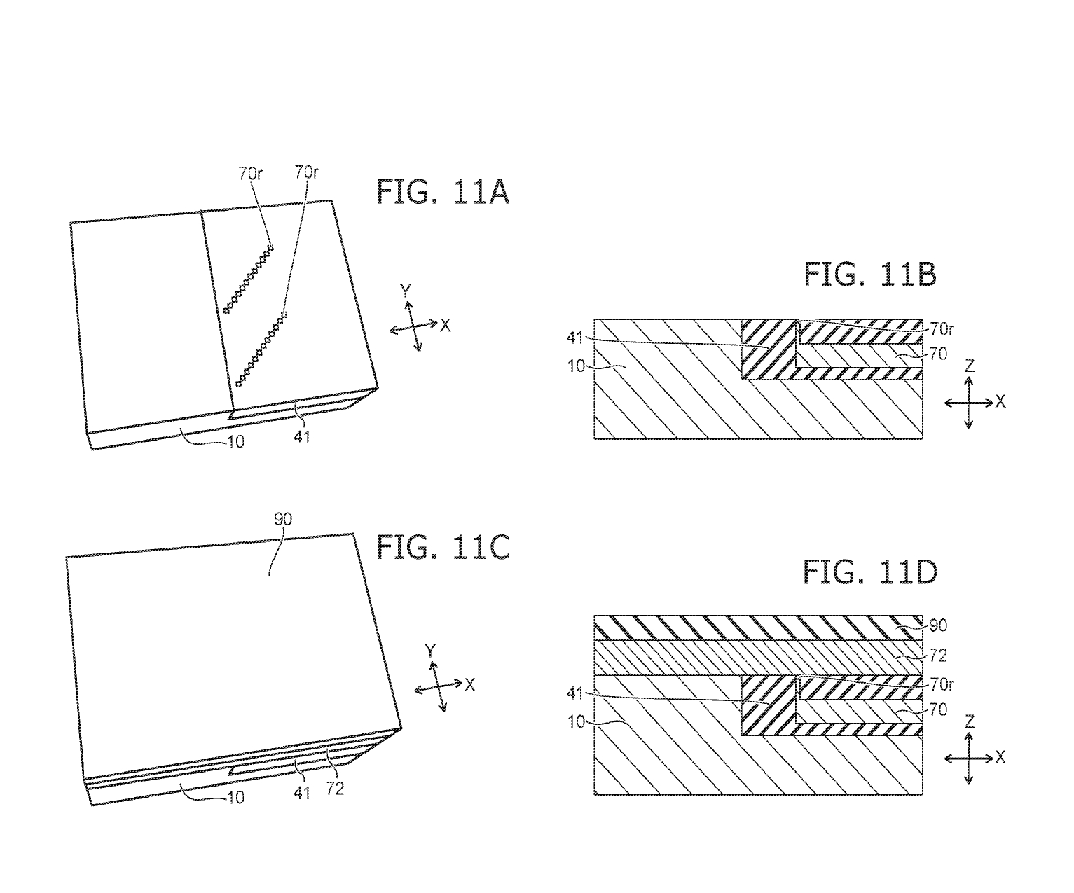

As shown in FIG. 11A and FIG. 11B, insulating films 70r are formed in the spaces 70p. The insulating films 70r are, for example, silicon nitride films. Hereby, the upper surfaces of the interconnects 70 are covered with the insulating films 70r. The upper surfaces of the insulating films 70r are coplanar with, for example, the upper surface of the substrate 10.

As shown in FIG. 11C and FIG. 11D, a protecting film 72 is formed on the substrate 10 and the insulating layer 41. For example, silicon doped with boron is used as the protecting film 72.

The protecting film 72 protects the insulating layer 41 and the interconnects 70 in formation of a channel body 20 described later. A resist film 90 is formed on the protecting film 72.

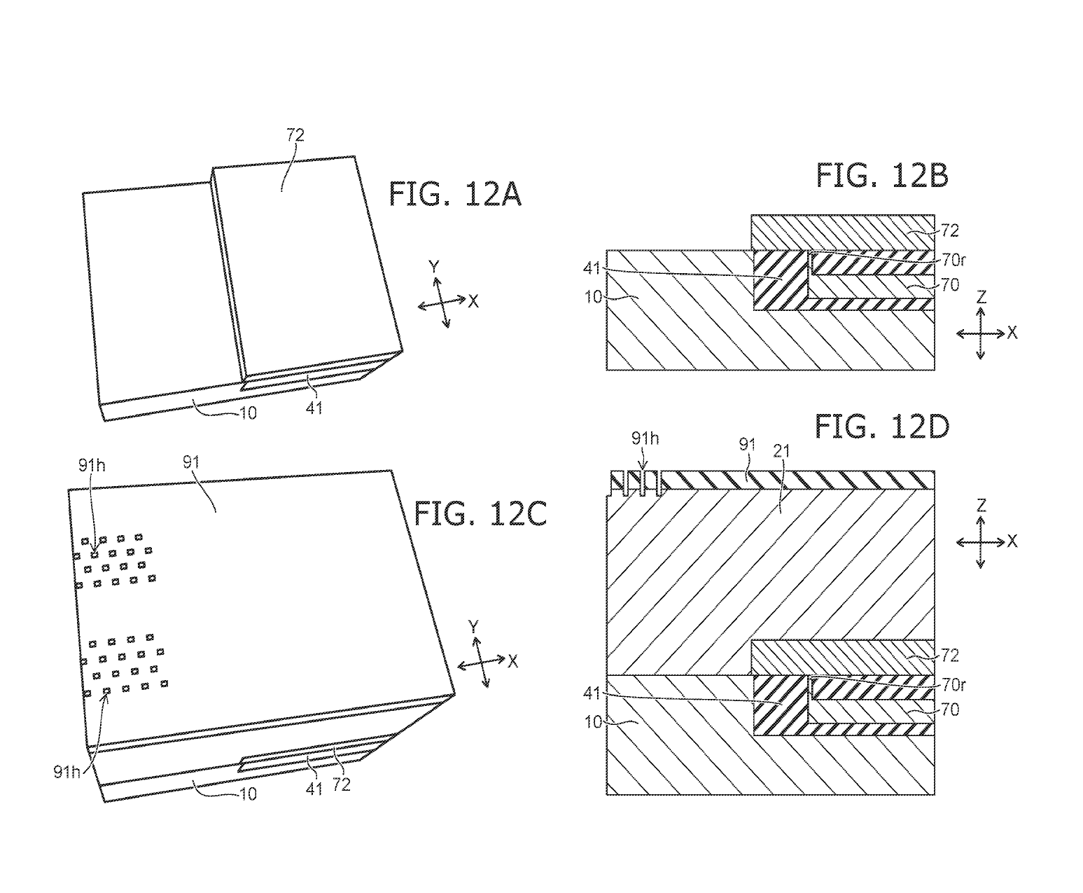

As shown in FIG. 12A and FIG. 12B, the upper surface of the substrate 10 is exposed. For example, the PEP method is used as a method of exposing the upper surface of the substrate 10, and the resist film 90 formed on the substrate 10 is removed. Thereafter, the protecting film 72 formed on the substrate 10 is removed by the RIE method using the resist film 90 as a mask. Hereby, the upper surface of the substrate 10 is exposed.

As shown in FIG. 12C and FIG. 12D, a sacrifice film 21 is formed on the substrate 10 and the protecting film 72. The thickness of the sacrifice film 21 influences the length of the after-mentioned channel body 20 extending in the Z-direction. For example, aluminum is used as the sacrifice film 21. The sacrifice film 21 may contain, for example, silicon.

A resist film 91 is formed on the sacrifice film 21. A pattern of exposing the upper surface of the sacrifice film 21 is formed in the resist film 91 by using, for example, the PEP method. Thereafter, the upper surface of the sacrifice film exposed in the pattern is recessed. Hereby, spaces 91h are formed in the upper end of the sacrifice film 21. The depth of the space 91h is small as compared with the thickness of the sacrifice film 21, and is, for example, 20 nm or less. For example, a nano in-print method not using the resist film 91 may be used as the forming method of the space 91h.

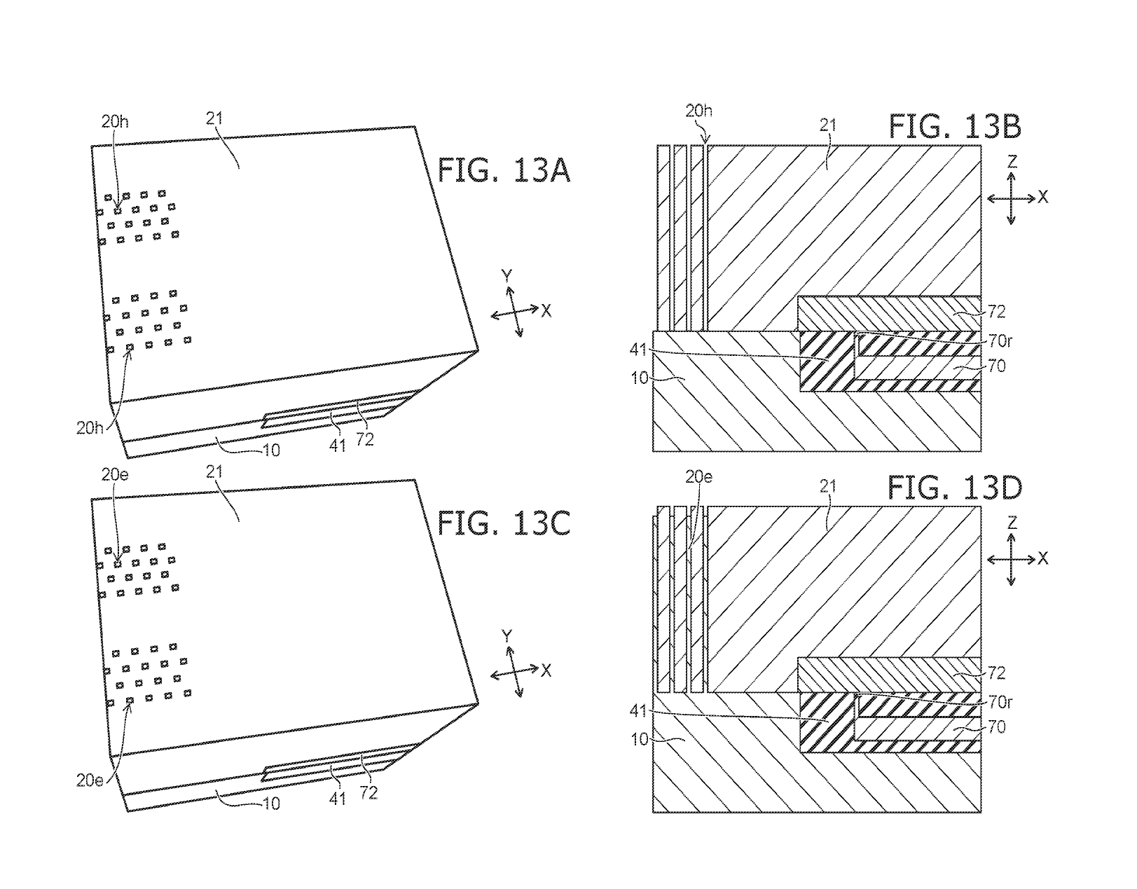

As shown in FIG. 13A and FIG. 13B, the resist film 91 is removed, and holes 20h are formed which pierce the sacrifice film 21 from the space 91h and reach the substrate 10.

For example, an electrolysis etching method of the sacrifice film 21 is used as a method of forming the holes 20h. The electrolysis etching method is performed in, for example, an acid solution, and the sacrifice film 21 is anodized. Hereby, the holes 20h are formed. The hole 20h has a diameter equal to, for example, that of the space 91h and extends in the Z-direction.

As shown in FIG. 13C and FIG. 13D, channel bodies 20e are formed in the holes 20h. The channel bodies 20e are formed by, for example, an epitaxial growth method using the substrate 10 exposed in the holes 20h as a nucleus. For example, a vapor-phase growth raw material gas and an HCl gas are used in the epitaxial growth method. At this time, since the sacrifice film 21 is oxidized by the foregoing process, the sacrifice film 21 is not eroded.

The channel body 20e contains, for example, silicon. The crystal structure orientation of the channel body 20e is equal to, for example, the crystal structure orientation of the substrate 10.

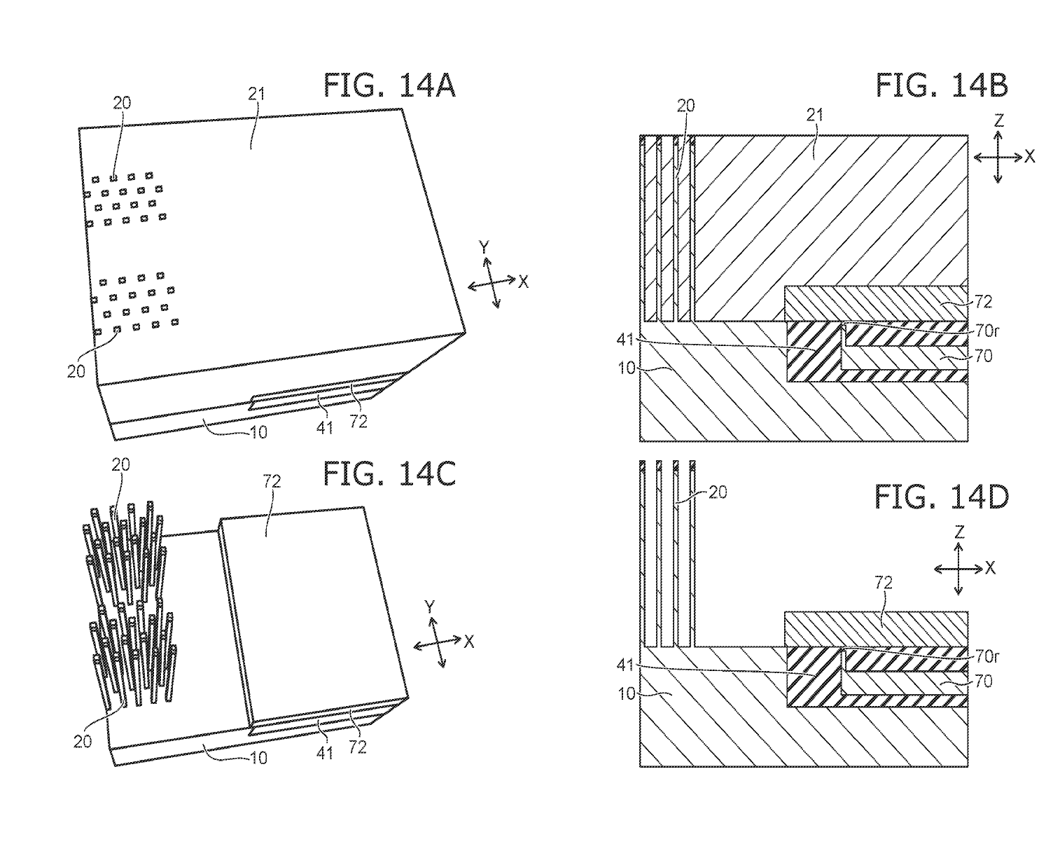

As shown in FIG. 14A and FIG. 14B, a cap film is formed on the channel bodies 20e, and the channel bodies 20 are formed. For example, a silicon nitride film is used as the cap film.

As shown in FIG. 14C and FIG. 14D, the sacrifice film 21 is removed, so that the channel bodies 20, the upper surface of the substrate 10 and the protecting film 72 are exposed. For example, sulfuric acid/hydrogen peroxide and DHF (diluted hydrofluoric acid) are used in a method of removing the sacrifice film 21.

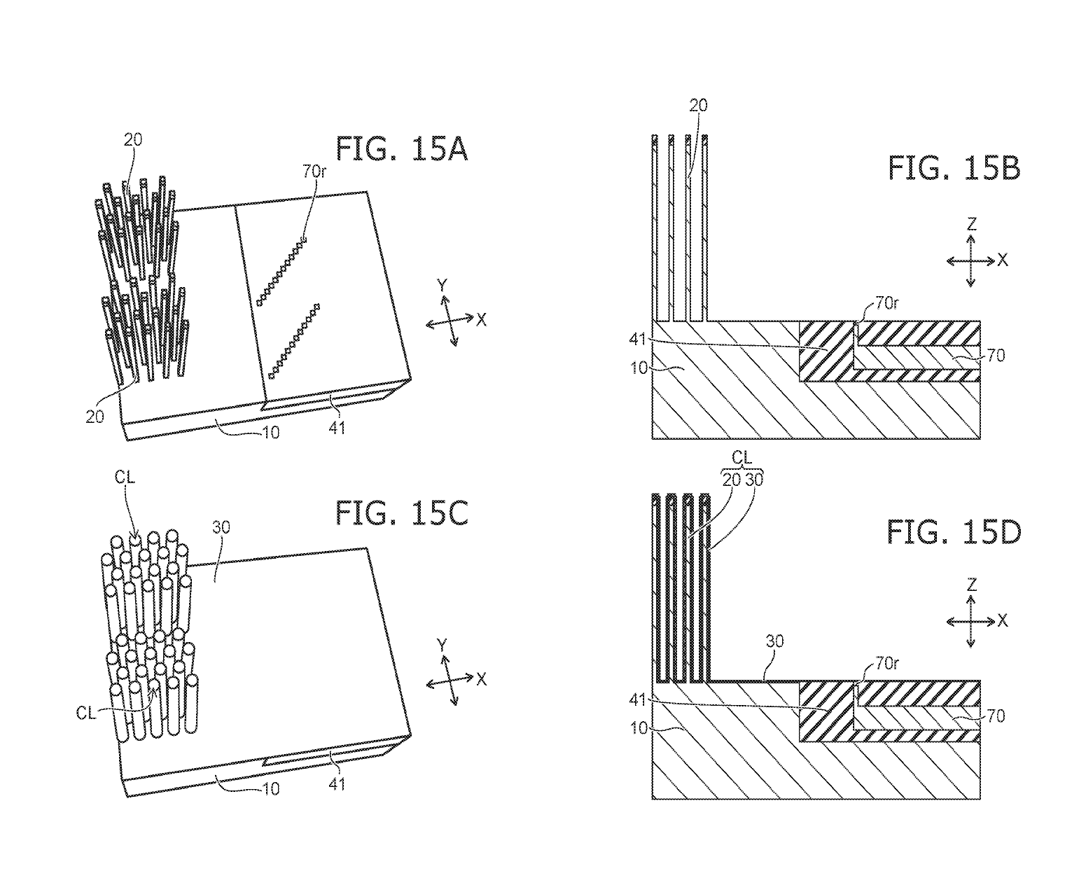

As shown in FIG. 15A and FIG. 15B, the protecting film 72 on the insulating layer 41 is removed. Hereby, the upper surface of the insulating layer 41 and the upper surface of the insulating film 70r are exposed.

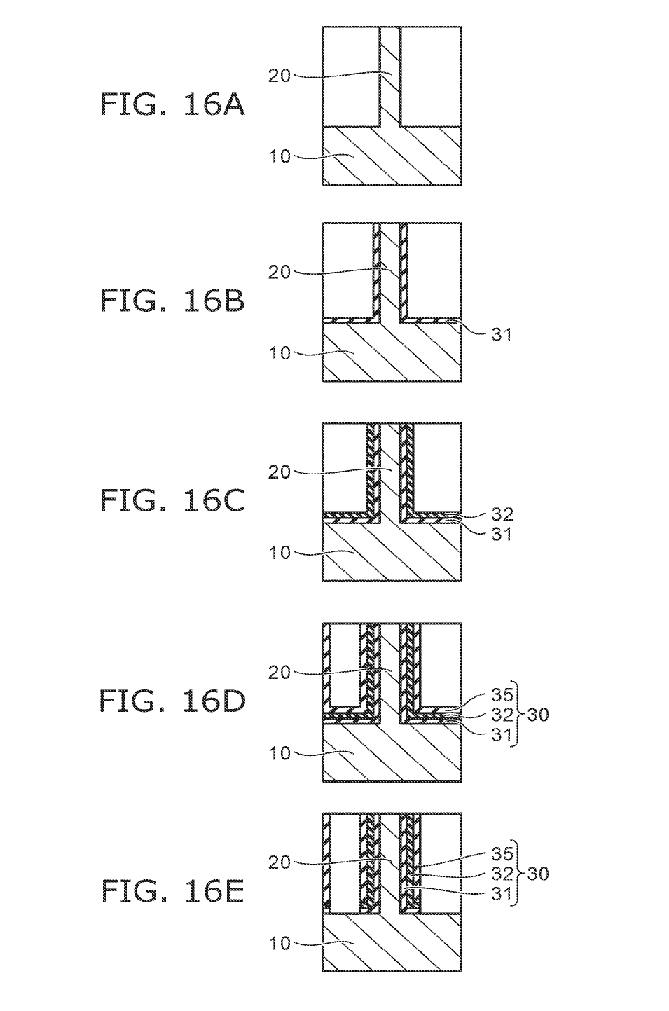

As shown in FIG. 15C to FIG. 16E, the memory film 30 shown in FIG. 2A is formed on the side surface of the channel body 20, on the substrate 10 and on the insulating layer 41. Hereby, the columnar portion CL is formed.

As shown in FIG. 16B, the tunnel insulating film 31 is conformally formed on the side surface of the channel body 20 and on the substrate 10. Hereby, the whole surface of the channel body 20 is covered with the tunnel insulating film 31.

As shown in FIG. 16C, the charge storage film 32 is conformally formed on the surface of the tunnel insulating film 31.

As shown in FIG. 16D, the block insulating film 35 is conformally formed on the surface of the charge storage film 32.

As shown in FIG. 16E, the respective films 31, 32 and 35 formed on the substrate 10 are removed. Hereby, the configuration shown in FIG. 2B can be formed in the lower end of the columnar portion CL.

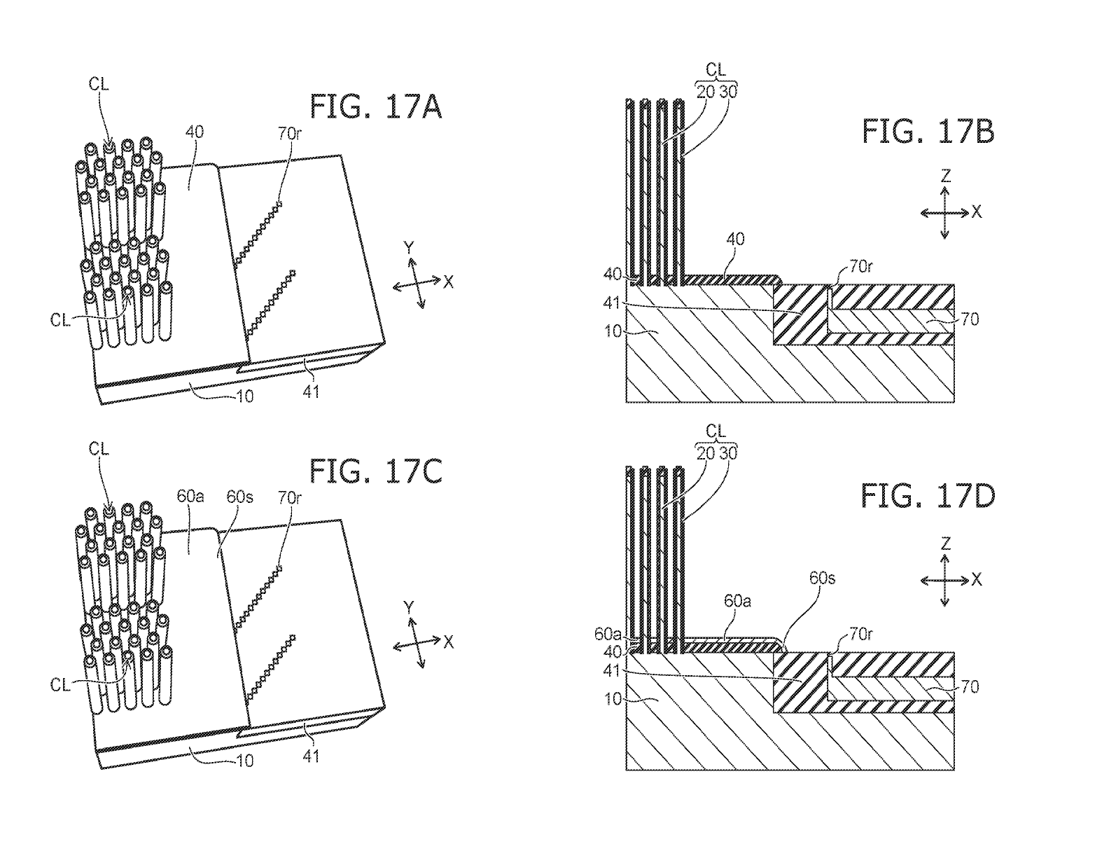

As shown in FIG. 17A and FIG. 17B, a sacrifice layer 40 is formed on the substrate 10 and on a part of the insulating layer 41. The sacrifice layer 40 is formed by, for example, the epitaxial growth method using the upper surface of the substrate 10 as a nucleus. For example, silicon germanium is used as the sacrifice layer 40.

At this time, the sacrifice layer 40 is formed also in the X-direction in addition to the Z-direction on the upper surface of the substrate 10. Hereby, the sacrifice layer 40 is formed also on the part of the insulating layer 41. The length of the sacrifice layer 40 formed in the X-direction can be controlled by, for example, the amount of vapor-phase growth raw material gas and HCl gas.

As shown in FIG. 17C and FIG. 17D, an electrode layer 60 is formed on the surface of the sacrifice layer 40. The electrode layer 60 is formed by, for example, the epitaxial growth method using the surface of the sacrifice layer 40 as a nucleus. For example, silicon is used as the electrode layer 60.

Incidentally, in the following, there is a case where a description is made while the electrode layer 60 formed on the substrate 10 is called an electrode layer 60a and the electrode layer 60 formed on the insulating layer 41 is called an electrode layer 60s (connection portion).

The electrode layer 60s is formed also on a part of the insulating layer 41 in addition to the surface of the sacrifice layer 40. At this time, the electrode layer 60s contacts the upper surface of the insulating film 70r. The electrode layer 60s contacts, for example, the upper surface of the insulating film 70r closest to the columnar portion CL.

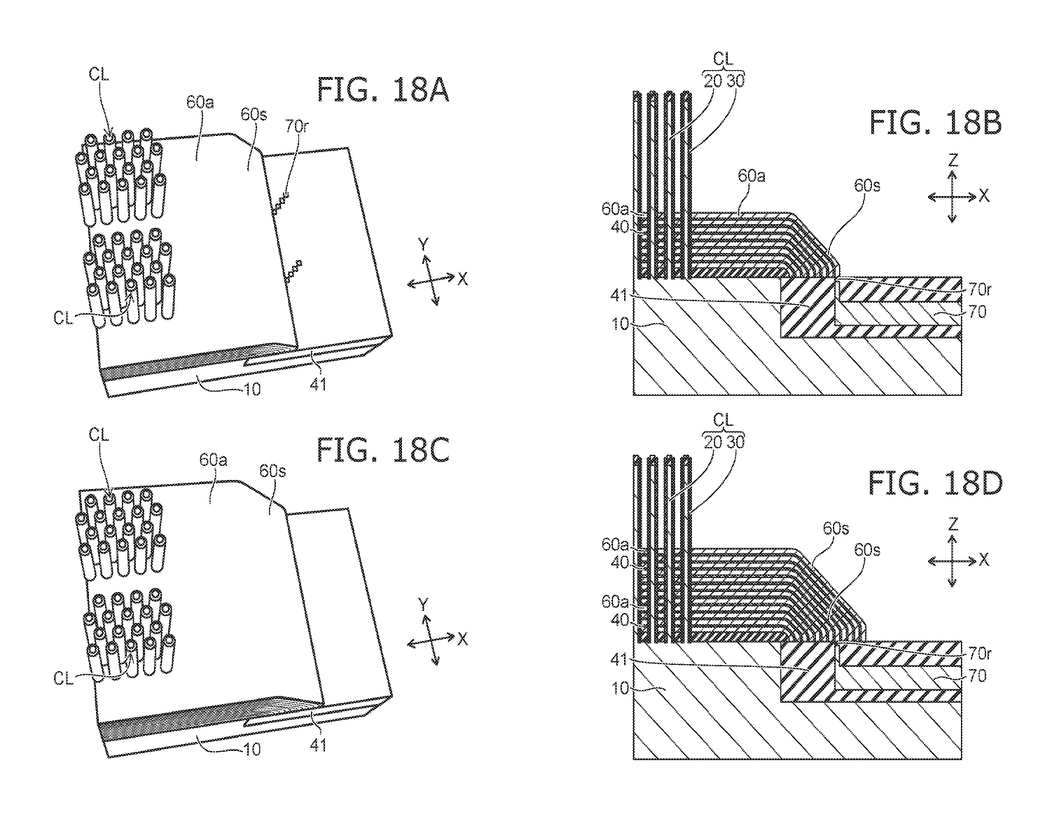

As shown in FIG. 18A to FIG. 18D, the sacrifice layer 40 and the electrode layer 60 are repeatedly formed. Hereby, the respective electrode layers 60 are separately stacked with each other through the sacrifice layer 40. The respective electrode layers 60s contact the different insulating films 70r, respectively.

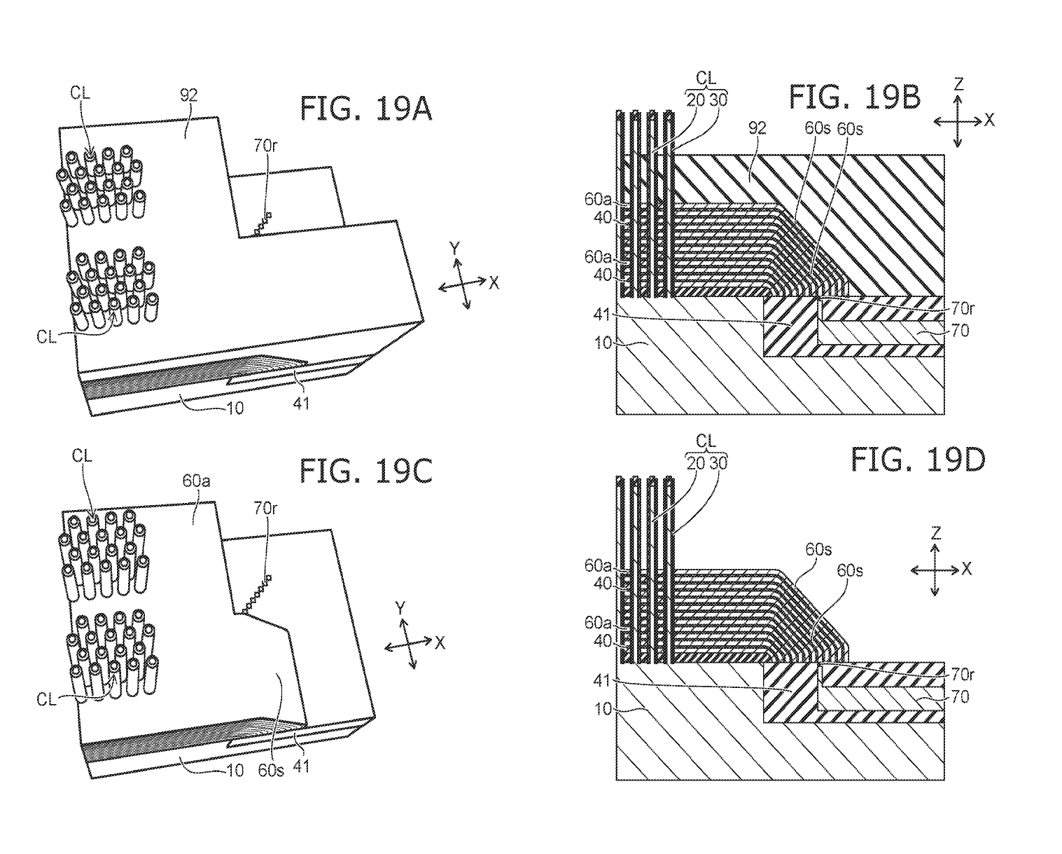

As shown in FIG. 19A and FIG. 19B, a resist film 92 is formed on the stacked electrode layers 60 and the insulating layer 41. A part of the resist film 92 formed on the insulating layer 41 through the multiple electrode layers 60s is removed by using, for example, the PEP method. Thereafter, the multiple electrode layers 60s and the multiple sacrifice layers 40 are exposed in the portion of the resist film 92 removed, and the multiple electrode layers 60s and the multiple sacrifice layers 40 are removed. Hereby, the upper surface of part of the insulating layer 41 and the upper surfaces of part of the insulating films 70r are exposed.

As shown in FIG. 19C and FIG. 19D, the resist film 92 is removed. Hereby, the upper surface of the electrode layer 60 is exposed.

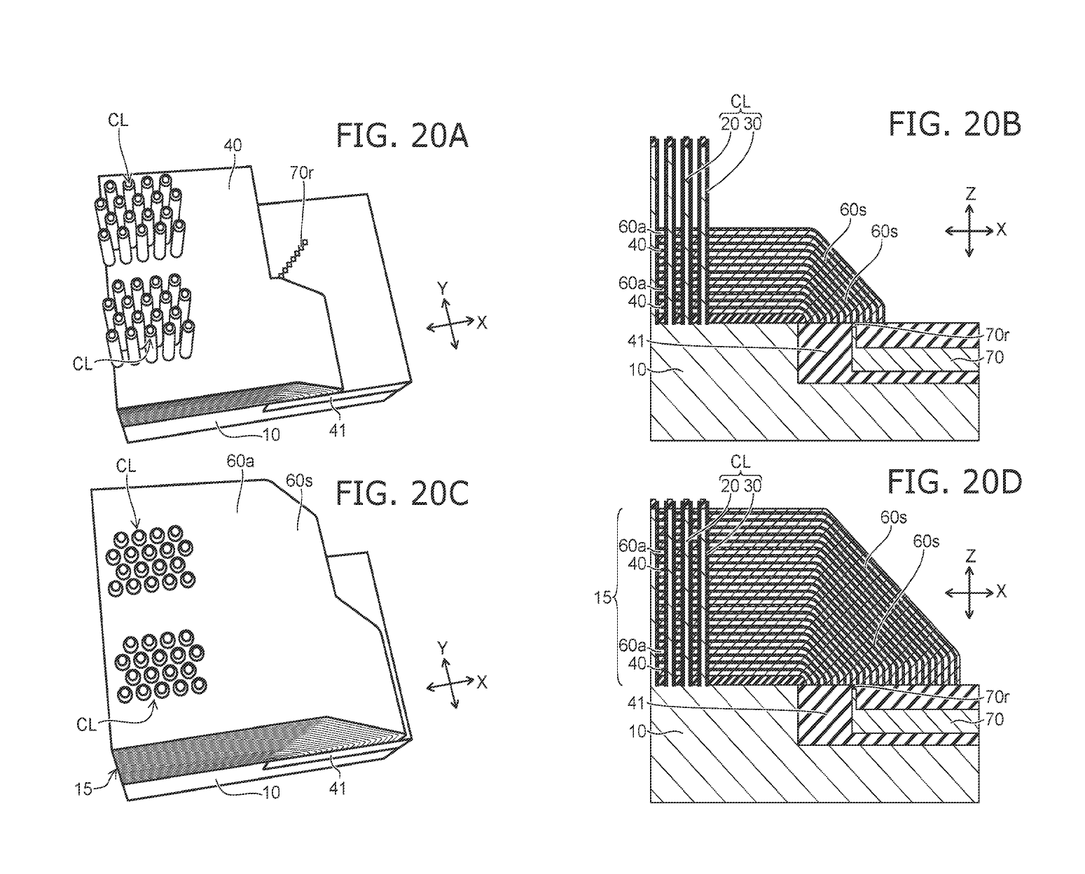

As shown in FIG. 20A to FIG. 20D, the sacrifice layer 40 and the electrode layer 60 are repeatedly formed. At this time, the respective formed electrode layers 60s contact the insulating films 70r exposed by the foregoing process.

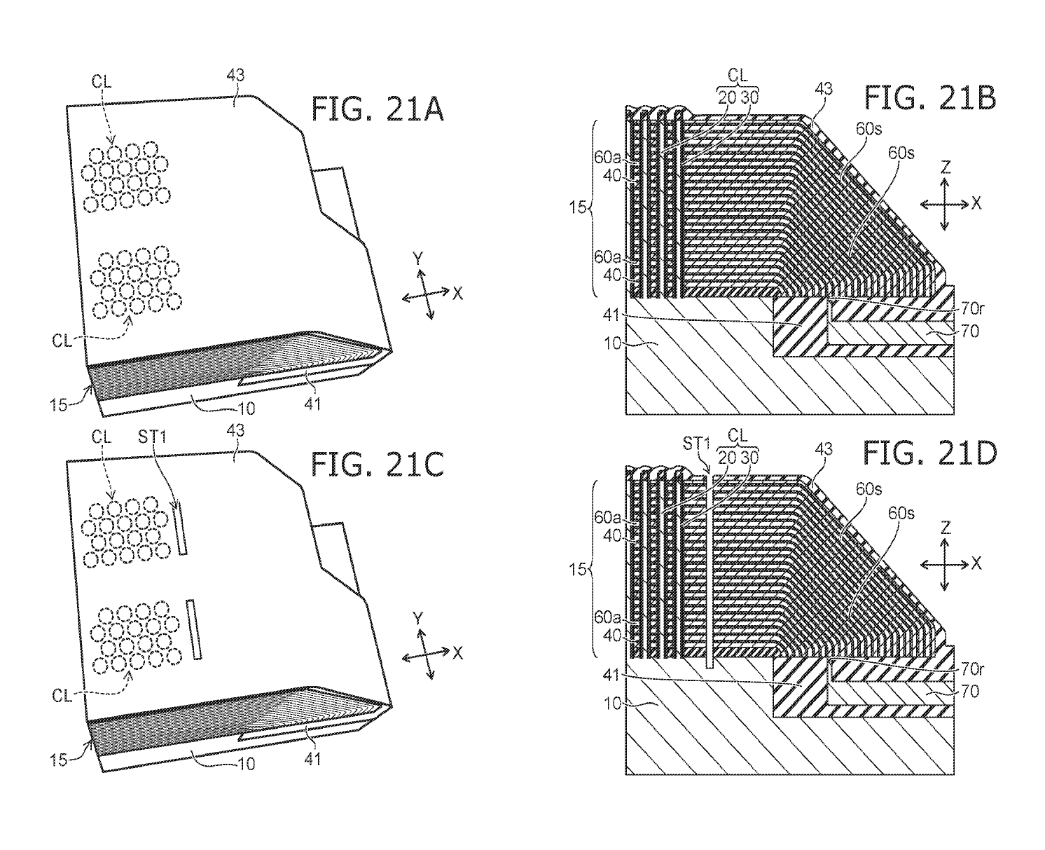

As shown in FIG. 21A and FIG. 21B, the stacked body 15 is formed in which the multiple electrode layers 60 and the multiple sacrifice layers 40 are formed. An insulating film 43 is formed on the stacked body 15. For example, a silicon oxide film is used as the insulating film 43. At this time, the columnar portions CL are covered with the insulating film 43.

As shown in FIG. 21C and FIG. 21D, a slit ST1 piercing the insulating film 43 and the stacked body 15 and reaching the substrate 10 is formed. The slit ST1 is formed by, for example, the RIE method using a not-shown mask.

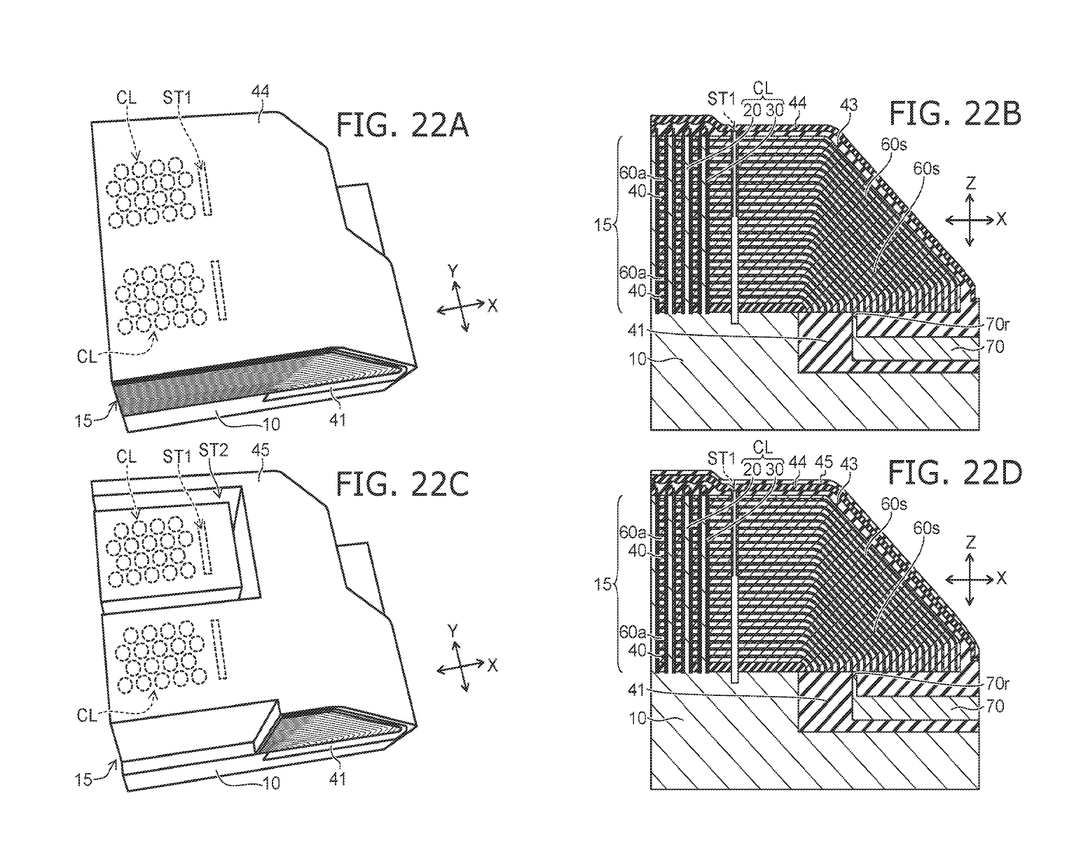

As shown in FIG. 22A and FIG. 22B, an insulating film 44 is formed on the insulating film 43 and the upper part of the slit ST1. Hereby, the upper part of the slit ST1 is closed by the insulating film 44. For example, a silicon oxide film is used as the insulating film 44.

As shown in FIG. 22C and FIG. 22D, a slit ST2 piercing the stacked body 15 and reaching the substrate 10 is formed in the periphery of the columnar portions CL. The interconnect portion LI shown in FIG. 3A is formed in the slit ST2 in a later process.

Thereafter, an insulating film 45 is formed on the inner wall of the slit ST2 and the insulating film 44. Hereby, the stacked body 15 exposed in the slit ST2 is covered with the insulating film 45. For example, a silicon oxide film is used as the insulating film 45.

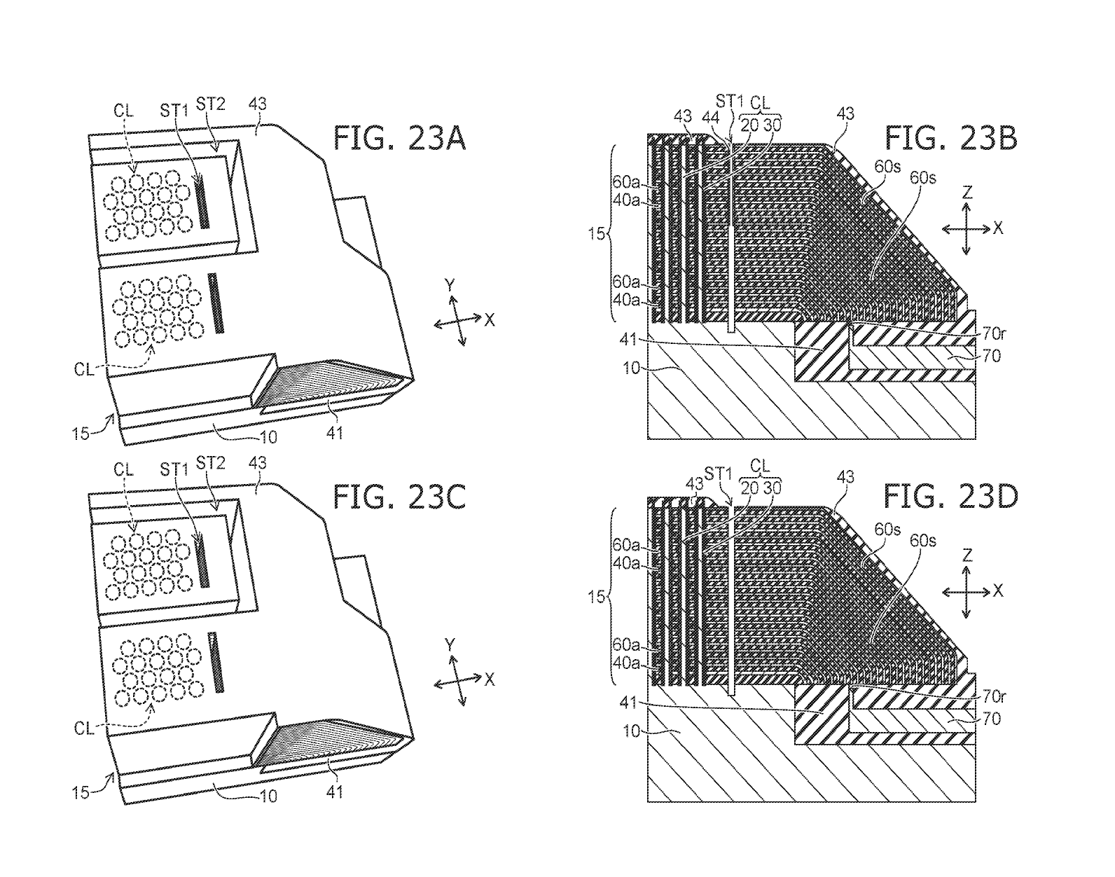

As shown in FIG. 23A and FIG. 23B, the respective insulating films 44 and 45 formed on the stacked body 15 are removed. Hereby, the slit ST1 is opened.

As shown in FIG. 23C and FIG. 23D, the insulating film 44 slightly formed on the inner wall of the slit ST1 is removed.

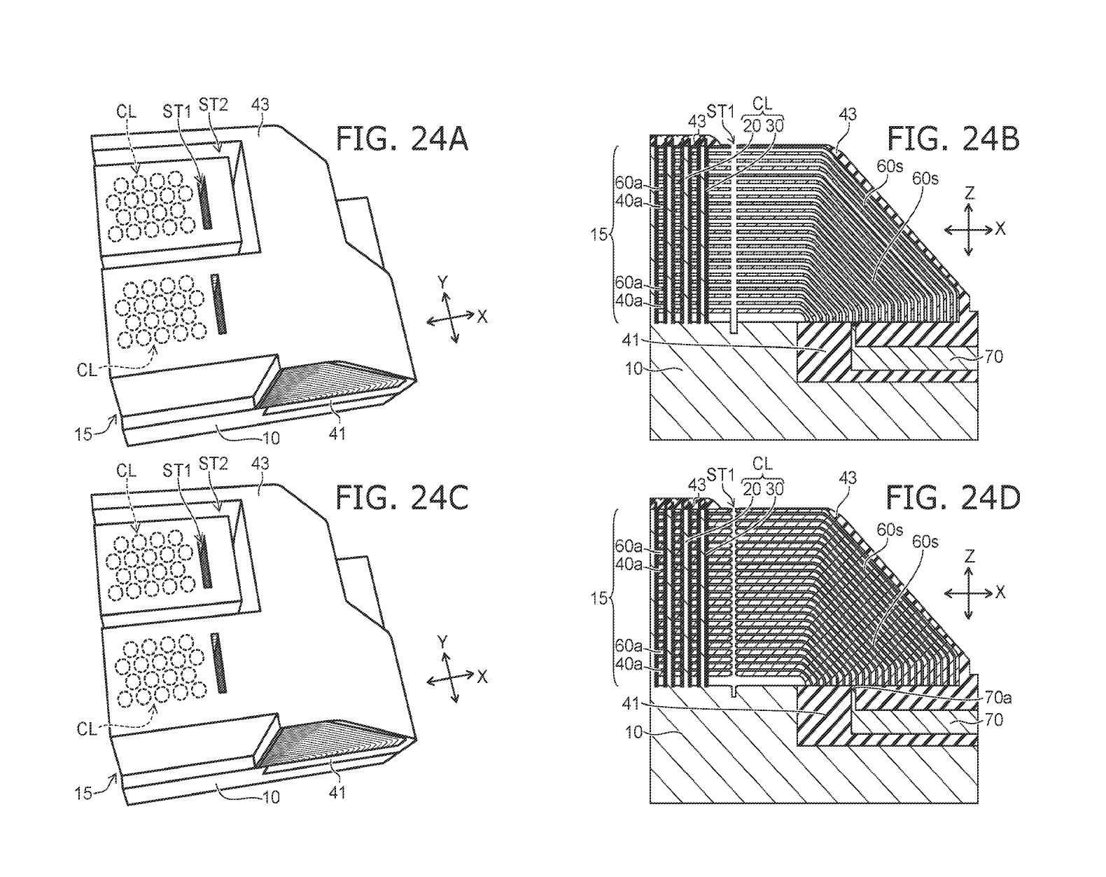

As shown in FIG. 24A and FIG. 24B, the sacrifice layer 40 is removed through the slit ST1. Hereby, cavities (insulating portions 40a) are formed in the portions where the sacrifice layer 40 is removed.

Thereafter, the insulating films 70r formed on the interconnects 70 are removed by, for example, a phosphoric acid treatment through the insulating portions 40a. Hereby, the respective electrode layers 60s on the insulating layer 41 are separated from the respective interconnects 70.

As shown in FIG. 24C and FIG. 24D, the ends 70a of the interconnects 70 are formed by the epitaxial growth method using the respective electrode layers 60 and the upper surfaces of the respective interconnects 70 as nuclei, and the ends 70a contact the electrode layers 60s. At this time, the respective electrode layers 60 become thick to such a degree that the mutually separated state is kept.

Thereafter, the interconnect portion LI is formed in the slit ST2, an upper layer interconnect and the like are formed, and the semiconductor memory device of the embodiment is formed.

According to the embodiment, the holes of the columnar portions CL are formed by using the electrolysis etching method. If the multiple holes are formed by using, for example, a dry etching, variation in diameters of the holes may increase according to the position in the depth direction. Besides, the center axis of the hole does not become a straight line and may be bent. Further, the holes having different depths may be formed. By theses, there is a fear that the characteristics of the columnar portions CL are degraded.

On the other hand, according to the embodiment, the high-precision holes can be formed as compared with the dry etching or the like. Hereby, degradation of characteristics can be suppressed.

Besides, the channel body 20 is formed integrally with the substrate 10. Hereby, the electric resistance between the channel body 20 and the substrate 10 can be reduced, and degradation of characteristics due to miniaturization can be suppressed.

Further, the lower end of the charge storage film 32 is separated from the channel body 20. Thus, degradation of characteristics of the memory cell MC can be suppressed.

In addition to the above, according to the embodiment, the multiple electrode layers 60s have surfaces in contact with the multiple ends 70a on the same plane. The epitaxial growth method is used as the process of connecting the electrode layer 61a and the end 70a. Hereby, high-precision formation of the connection portion is enabled as compared with a process of forming the connection portion by processing the electrode layer 60s. Thus, degradation of characteristics due to miniaturization can be suppressed.

Further, according to the embodiment, the electrode layer 60s connected to the end 70a is formed integrally with the electrode layer 60a of the memory cell MC. Hereby, interfaces between members are small between the electrode layer 60a and the interconnect 70 as compared with a case where a connection member such as a contact portion is formed. Thus, the electric resistance between the electrode layer 60a and the interconnect 70 can be reduced, and degradation of characteristics due to miniaturization can be suppressed.

According to the embodiment, the multiple ends 70a formed side by side in the Y-direction contact the different electrode layers 60s, respectively. Hereby, enlargement of the area in the X-direction due to increase of the multiple interconnects 70 can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device, comprising:
a substrate;
a stacked body provided on the substrate and including multiple electrode layers separately stacked with each other;
a semiconductor film provided integrally with the substrate in the stacked body, extending in a stacking direction of the stacked body, an orientation of a crystal structure of the semiconductor film being equal to an orientation of a crystal structure of the substrate;
a charge storage film provided between the semiconductor film and the multiple electrode layers; and
a first insulating film provided between the semiconductor film and the charge storage film, the first insulating film extending in the stacking direction and having a bottom surface contacting the substrate.

2. The device according to claim 1, wherein
the charge storage film extends in the stacked direction, and
the bottom surface of the first insulating film is closer to the substrate than a bottom surface of the charge storage film.

3. The device according to claim 2, wherein
the bottom surface of the charge storage film contacts the first insulating film.

4. The device according to claim 2, wherein
the charge storage film is separated from the semiconductor film.

5. The device according to claim 2, wherein
an area of the bottom surface of the first insulating film is larger than an area of the bottom surface of the charge storage film.

6. The device according to claim 2, further comprising:
a second insulating film provided between the multiple electrode layers and the charge storage film, and extending in the stacking direction,
the bottom surface of the charge storage film is closer to the substrate than a bottom surface of the second insulating film.

7. The device according to claim 6, wherein
an area of the bottom surface of the charge storage film is larger than an area of the bottom surface of the second insulating film.

8. The device according to claim 6, wherein
the second insulating film is separated from the semiconductor film.

9. The device according to claim 1, wherein the semiconductor film is columnar.

10. The device according to claim 1, wherein the semiconductor film contains silicon.

11. The device according to claim 1, wherein the semiconductor film contains aluminum.

12. The device according to claim 1, wherein
the stacked body includes
a first electrode layer,
a second electrode layer provided separately on the first electrode layer, and
an air gap provided between the first electrode layer and the second electrode layer.

13. The device according to claim 1, further comprising:
multiple interconnects provided between the substrate and the stacked body,
the multiple electrode layers include
a first electrode layer extending in a first direction crossing the stacking direction,
a second electrode layer provided on the first electrode layer, and extending in the first direction,
a first connection portion provided integrally with the first electrode layer, and
a second connection portion provided integrally with the second electrode layer, the second connection portion separated from an upper surface of the first connection portion and covering the upper surface of the first connection portion,
the multiple interconnects include
a first interconnect including a first end connected to the first connection portion, and
a second interconnect including a second end connected to the second connection portion, the second interconnect separated from the first interconnect,
a surface of the first connection portion in contact with the first end is coplanar with a surface of the second connection portion in contact with the second end.

14. The device according to claim 13, wherein
the multiple interconnects are provided below a lower end of the semiconductor film.

15. A method for manufacturing a semiconductor memory device, comprising:
forming a sacrifice film on a substrate;
forming a hole piercing the sacrifice film and reaching the substrate;
forming a semiconductor film in the hole;
removing the sacrifice film;
forming a film including a charge storage film on a side surface of the semiconductor film; and
forming a stacked body including multiple first layers stacked separately from each other on the substrate and a side surface of a film including the charge storage film.

16. The method according to claim 15, wherein the forming the semiconductor film includes forming the semiconductor film by an epitaxial growth method using the substrate as a nucleus.

17. The method according to claim 15, wherein
the forming the hole includes forming the hole by using an electrolysis of the sacrifice film.

18. The method according to claim 17, wherein the sacrifice film contains aluminum.

19. The method according to claim 15, wherein
the forming the film including the charge storage film includes
forming a first insulating film on the substrate and a side surface of the semiconductor film, and
forming the charge storage film separated from the semiconductor film on a side surface of the first insulating film.

20. The method according to claim 15, further comprising:
forming multiple interconnects between the substrate and the stacked body, the multiple interconnects including a first interconnect and a second interconnect separated from the first interconnect,
the forming the stacked body includes
forming a first sacrifice layer on a surface of the substrate and a side surface of a film including the charge storage film,
forming a first layer on the side surface of the film including the charge storage film, the multiple interconnects, and a surface of the first sacrifice layer,
forming a second sacrifice layer on the side surface of the film including the charge storage film, the multiple interconnects, and a surface of the first layer,
forming a second layer on the side surface of the film including the charge storage film, the multiple interconnects, and a surface of the second sacrifice layer,
removing the first sacrifice layer and the second sacrifice layer,
connecting the first interconnect to the first layer, and
connecting the second interconnect to the second layer.
